(19) United States
(12) Patent Application Publication
(10) Pub. No.: US 2024/0320211 A1
(43) Pub. Date: Sep. 26, 2024

(54) SYSTEMS AND METHODS FOR DATA CLUSTERING USING MACHINE LEARNING

(71) Applicant: ADOBE INC., SAN JOSE, CA (US)

(72) Inventors: Rebecca Dorothy West, Auburn, CA (US); Lauren Dest, Austin, TX (US); Mihir Naware, Redwood City, CA (US); Elliot Axel Patrick Puzenat, Le Plessis Robinson (FR); Stephen Becigneul, Levallois-Perret (FR); Alexis Tessier, Eckwersheim (FR); Suman Basetty, Fremont, CA (US); Kimberly K. Lenox, Orinda, CA (US); Anil Kamath, Los Altos HIlls, CA (US)

(21) Appl. No.: 18/477,670

(22) Filed: Sep. 29, 2023

Related U.S. Application Data
(60) Provisional application No. 63/491,499, filed on Mar. 21, 2023.

(51) Int. Cl. G06F 16/242; G06F 16/28

(52) U.S. Cl. CPC G06F 16/242; G06F 16/285

(57) ABSTRACT

A method, non-transitory computer readable medium, apparatus, and system for data clustering are described. An embodiment of the present disclosure includes receiving, by a machine learning model, a prompt. The machine learning model generates a structured query for a database of users based on the prompt. A user experience platform generates a user segment of the users based on the structured query.

### CROSS-REFERENCE TO RELATED APPLICATION

This application claims the benefit, under 35 U.S.C. § 119, of the filing date of U.S. Provisional Application No. 63/491,499, filed on Mar. 21, 2023, in the United States Patent and Trademark Office. The disclosure of U.S. Provisional Application No. 63/491,499 is incorporated by reference herein in its entirety.

### BACKGROUND

The following relates generally to data processing, and more specifically to data clustering using machine learning. Data processing refers to a collection and manipulation of data to produce meaningful information. Machine learning is an information processing field in which algorithms or models such as artificial neural networks are trained to make predictive outputs in response to input data without being specifically programmed to do so.

In some cases, a set of data, such as a dataset for a group of users, is analyzed to identify a segment of the data having a shared quality or attribute. However, in some cases, a process of determining an optimized query for analyzing the data set to determine a relevant data segment is both time-intensive and labor-intensive. There is therefore a need in the art for a data processing system that clusters data in an efficient manner.

### SUMMARY

Embodiments of the present disclosure provide a data processing system that generates a user segment based on a structured query generated by a machine learning model. By generating the structured query using the machine learning model, the data processing system is able to identify the user segment in a less time-consuming and labor-intensive manner than conventional data processing systems.

A method, apparatus, non-transitory computer readable medium, and system for data clustering are described. One or more aspects of the method, apparatus, non-transitory computer readable medium, and system include receiving a prompt; generating a structured query for a database of users based on the prompt; and generating a user segment of the users based on the structured query.

A method, apparatus, non-transitory computer readable medium, and system for data clustering are described. One or more aspects of the method, apparatus, non-transitory computer readable medium, and system include obtaining training data that includes a training prompt and a ground-truth structured query and training a machine learning model to generate structured queries for a database of users using the training data.

A system and an apparatus for data clustering are described. One or more aspects of the system and the apparatus include at least one processor; at least one memory storing instructions executable by the at least one processor; a user interface configured to receive a prompt; a machine learning model including parameters stored in the at least one memory and trained to generate a structured query for a database of users based on the prompt; and a user experience platform configured to generate a user segment of the users based on the structured query.

### BRIEF DESCRIPTION OF THE DRAWINGS

FIG. 1 shows an example of a data processing system according to aspects of the present disclosure.

FIG. 2 shows an example of a data processing apparatus according to aspects of the present disclosure.

FIG. 3 shows an example of a transformer according to aspects of the present disclosure.

FIG. 4 shows an example of data flow in a data processing system according to aspects of the present disclosure.

FIG. 5 shows an example of a method for querying a database for a user segment according to aspects of the present disclosure.

FIG. 6 shows an example of a method for generating a user segment according to aspects of the present disclosure.

FIG. 7 shows an example of a user interface for determining a user segment according to aspects of the present disclosure.

FIG. 8 shows an example of a user interface for a query according to aspects of the present disclosure.

FIG. 9 shows an example of a method for training a machine learning model according to aspects of the present disclosure.

### DETAILED DESCRIPTION

In some cases, a set of data, such as a dataset for a group of users, is analyzed to identify a segment of the data having a shared quality or attribute. For example, in some cases, content distribution and user experience strategies are informed by a wide variety of factors, including ever-changing user segments, user preferences, market trends, and signals from social, economic, and political landscapes. An ability to quickly and intelligently understand, plan for, and react to such factors greatly assists a content provider in achieving its goals.

At the same time, users are increasingly embracing digital channels to engage with content providers and are demanding that content providers personalize their interactions. Therefore, both users and content providers benefit when an intent, stage, and context of users are understood and a digital experience is tailored for the users. In some cases, a confluence of personalization at scale along with a myriad of macro influences presents an opportunity for a data processing system for digital user experience management that operates at a granularity of an individual user's journey and sequence of experiences, all while helping a content provider to achieve its goals.

However, producing an effective content distribution campaign by identifying a relevant user segment, synthesizing external and internal data into actionable opportunities, creating superior campaign components (e.g., content, journeys, objectives, etc.) tailored for the relevant user segment, and optimizing a content distribution strategy for the user segment over time is not easily achievable for a content provider team, and added challenges of a demand from content providers for new, fresh, and personalized user experiences and siloed teams balancing various overlapping efforts creates further complication for creating an effective campaign.

For example, in some cases, a superior campaign draws upon vast and disparate external and internal data that individual strategists and analysts are not able to effectively comprehend or synthesize within an allotted time. In some cases, a significant part of an analyst's time is spent on retrieving basic key performance indicator (KPI) questions with little bandwidth for deep analysis, while in some cases, strategists such as campaign owners and managers rely on an ad hoc analysis of internal and external sources from analysts to identify a relevant user segment and to come to a point solution campaign.

Furthermore, in some cases, a process of conceiving, executing, and evaluating a campaign is laborious and time-consuming and is constrained both by a number of available team members and an ability to rapidly and effectively respond to quickly moving user preferences. Additionally, in some cases, an end-to-end content distribution effort is scattered across different roles, making an ability to quickly and dynamically adjust campaign components based on ever-changing trends a challenge.

For example, in some cases, strategists rely on operations teams, creative teams, and other team members to execute a point solution campaign. During such a process, in some cases, a performance-based adjustment to the campaign is time-consuming, as the adjustment demands waiting for a full cycle to re-engage team members that are now occupied with different tasks. Additionally, in some cases, a content distribution effort is hampered by a lack of healthy knowledge-sharing practices across teams, resulting in silos, inefficiencies, and bottlenecks.

Still further, in some cases, content distribution workflows are heavy, manual, and dependent upon a constant supply of human ingenuity and accuracy. For example, in some cases, operations team members that are focused on building user journeys perform numerous iterations according to an intuition of what aspects of a prospective user journey might be effective. Additionally, in some cases, creative team members have a limited capacity to create variations of content for campaigns, particularly based on historical performance and content affinity variations for clients and consumers.

Additionally, in some cases, an ability to create a tailored experience and user journey for each unique user is constrained by an ability of content provider teams to generate and deliver appropriate content at an appropriate time.

According to some aspects, a data processing system includes a machine learning model and a user experience platform. In some cases, the machine learning model is trained to generate a structured query for a database of users based on a prompt. In some cases, the user experience platform is configured to generate a user segment of the users based on the structured query.

By generating the structured query using the machine learning model, the data processing system is able to identify the user segment in a less time-consuming and labor-intensive manner than conventional data processing systems.

Accordingly, based on a content provider's guidance, the machine learning model assists with an ideation, definition, expansion, and refinement of a user segment for a content distribution campaign. In some cases, the machine learning model helps qualify and quantify the user segment using summary statistics and described traits of the user segment along with projected performance of the user segment towards the content provider's objective.

A data processing system according to an aspect of the present disclosure is used in a content distribution context. In an example, the data processing system identifies a data trend (e.g., an increase in solo travelers) in a data set that the data processing system is monitoring for a content provider. The data processing system alerts the content provider about the data trend (for example, via a user interface provided on a content provider device by the data processing system).

The content provider wants to identify a user segment of users that corresponds to the data trend. The content provider provides a text input to the user interface asking the data processing system to identify relevant groups of users (e.g., “Which audiences are traveling solo?”). A user experience platform generates a prompt by including one or more of the text input and contextual information (such as content provider profile information for the content provider, information corresponding to the data trend, historical interaction data for the content provider, etc.) in the prompt. The user experience platform provides the prompt to the machine learning model.

The machine learning model generates a structured query for searching a database of users according to the prompt. In some cases, the data processing system provides the data corresponding to the identified data trend to the machine learning model. In some cases, according to the prompt, the machine learning model translates semantics of the data corresponding to the identified data trend into the structured query. In an example, the machine learning model receives the prompt, and based on the data corresponding to the identification of an increase in solo travelers and the question “Which audiences are traveling solo?”, generates a structured query for identifying segments of users who are traveling solo among a set of user profiles stored in a database. The machine learning model provides the structured query to a user experience platform.

The user experience platform generates the user segment by querying the database of users using the structured query. The database returns a list of user identifiers who correspond to the data trend. For example, user profiles that include data corresponding to a “dual income, no kids” demographic are determined to correspond to the data trend based on the structured query, and the database returns user identifiers of the user profiles of the “dual income, no kids” users to the user experience platform.

The user experience platform provides an identification of the user segment to the content provider via the user interface. In some cases, the user experience platform provides the user profiles of the user segment to the machine learning model. In some cases, the user experience platform retrieves and/or generates a visual element (such as an image) corresponding to the user segment. In some cases, the user experience platform displays the visual element via the user interface.

In some cases, the machine learning model generates a description of the user segment and/or an evaluation of a likelihood that a member of the user segment will perform an action. In some cases, the user interface displays the description and/or the evaluation of the user segment to the content provider.

In some cases, the data processing system customizes content for the user segment. In some cases, the data processing system provides the customized content to one or more users of the user segment.

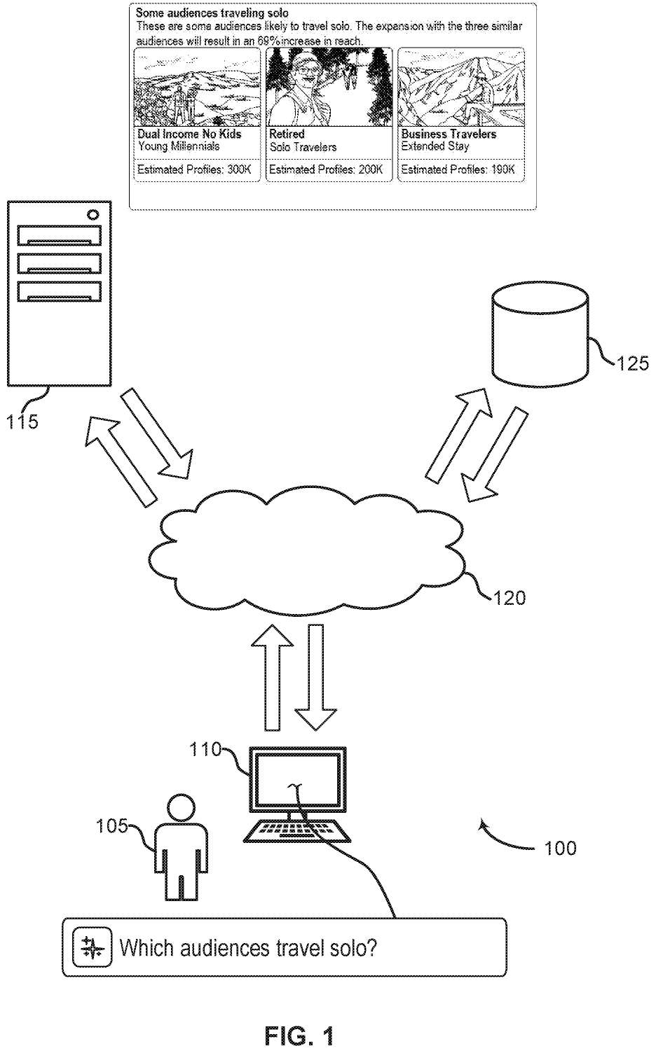

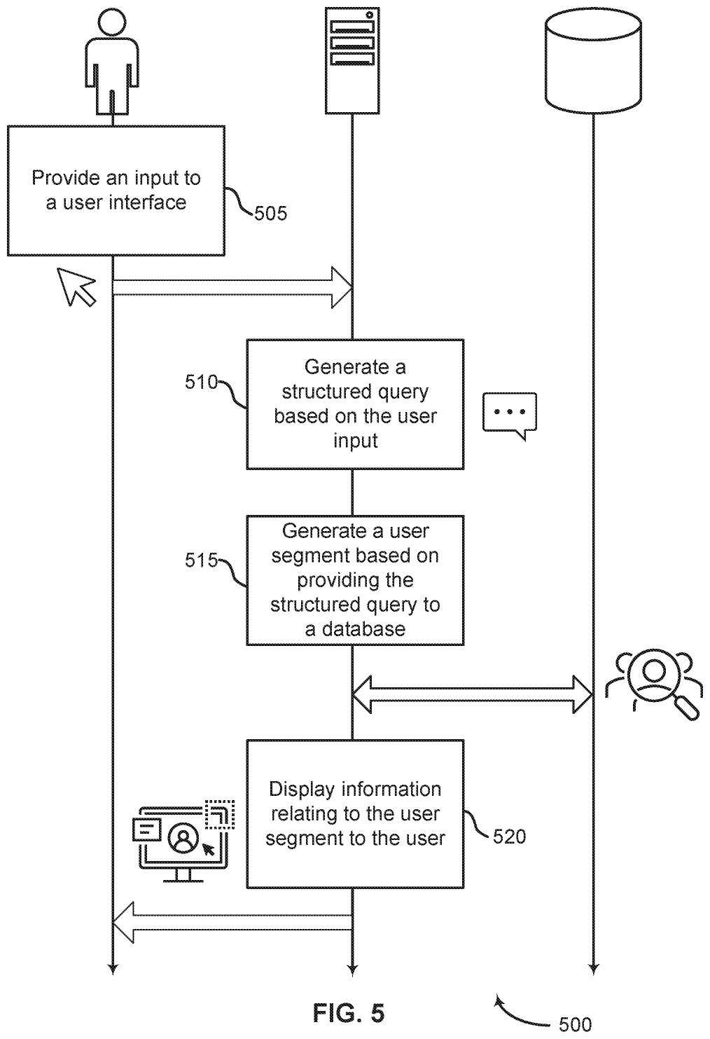

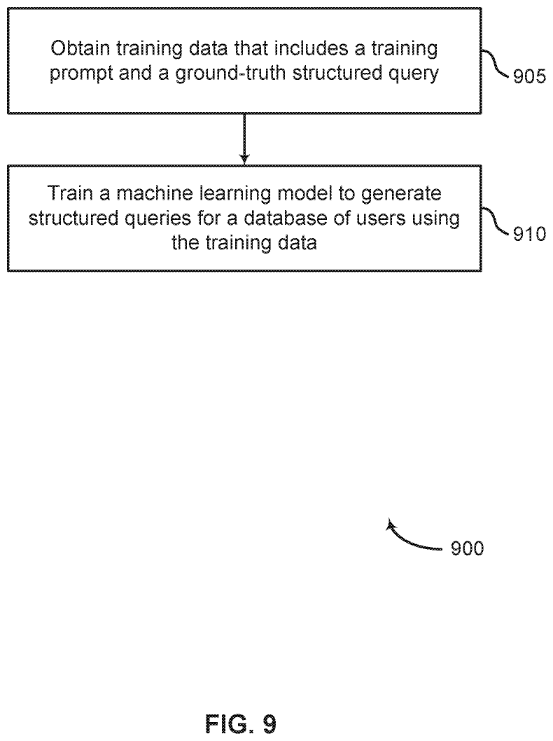

Further example applications of the present disclosure in the content distribution context are provided with reference to FIGS. 1 and 5. Details regarding the architecture of the data processing system are provided with reference to FIGS. 1-4. Details regarding a process for data clustering are provided with reference to FIGS. 5-8. Details regarding a process for training a machine learning model are provided with reference to FIG. 9.

As used herein, in some cases, a “content provider” refers to a person or entity that interacts with the data processing system and/or data processing apparatus. As used herein, “content” refers to any form of media, including goods, services, physically tangible media, and the like, and digital content, including media such as text, audio, images, video, or a combination thereof. As used herein, a “communication channel” or a “content distribution channel” refers to a physical channel (such as a mailing service, a physical location such as a store, a hotel, an amusement park, etc., and the like) or a digital channel (such as a website, a software application, an Internet-based application, an email service, a messaging service such as SMS, instant messaging, etc., a television service, a telephone service, etc.) through which content or digital content is provided. As used herein, “customized content” refers to content that is customized according to data associated with a content provider or a user.

As used herein, a “structured query” refers to a statement provided in a structured query language (SQL). In some cases, SQL is a programming language for storing and processing information in a database. In some cases, SQL integrates with various programming languages. In some cases, the structured query is embedded with a programming language. In some cases, the structured query includes common keywords. In some cases, a database stores information in tabular form according to SQL, with rows and columns representing different data attributes and the various relationships between the data values. In some cases, the structured query is used to store, update, remove, search, or retrieve information from the database organized according to one or more SQL tables. In some cases, a structured query includes a translation by a machine learning model of information included in or associated with a prompt into SQL.

As used herein, a “prompt” refers to an input to the machine learning model. In some cases, the prompt includes a natural language input. As used herein, “natural language” refers to any language that has emerged through natural use. In some cases, the prompt is generated by the user experience platform. In some cases, the prompt is generated in response to a content provider input to an element of a user interface. In some cases, the prompt includes contextual information, such as one or more of data corresponding to a data trend or anomaly, a text description of a suggested content distribution campaign provided by the content generation apparatus, data corresponding to information displayed on a user interface, a content provider profile for the content provider, content provider preferences (such as a campaign objective, a campaign goal, a preferred user segment, a preferred communication channel, preferred content, etc.), a content provider playbook, a historical content distribution campaign for the content provider, the targeted solo-traveling user segments, a key performance indicator, a user journey for the content provider, previous content provider feedback, and any other available content provider information or user information. In some cases, the prompt includes an instruction for the machine learning model to generate an output specified by the instruction. In some cases, the prompt comprises text (such as natural language text) provided by the content provider to the user interface. In some cases, the prompt includes one or more embeddings.

As used herein, in some cases, a “user experience platform” includes a set of creative, analytics, social, advertising, media optimization, targeting, Web experience management, journey orchestration and content management tools. In some cases, the user experience platform communicates with a database. In some cases, the user experience platform comprises the database. In some cases, the user experience platform comprises one or more artificial neural networks (ANNs) configured to generate content in response to an input.

As used herein, a “user segment” refers to a group of users corresponding to a group of user profiles and identified by a group of user identifiers. As used herein, a “user profile” refers to data corresponding to a user. Examples of data corresponding to a user include a name, contact information, demographic data, user device information, a purchase history, a correspondence history, and any other data relating to the user. As used herein, a “user identifier” refers to a unique identifier (such as a name, an email address, an identification number, etc.) for a user. In some cases, a user profile includes a user identifier. In some cases, the user segment includes one or more users corresponding to user profiles that include a common attribute or quality.

Accordingly, in some cases, because the structured query is generated by a machine learning model, the data processing system is able to more quickly and efficiently generate a user segment than conventional data processing systems.

Furthermore, unlike conventional data processing systems which use employ generative machine learning, according to some aspects, the data processing system goes beyond image and text generation to deliver insights and opportunities to a content provider to create a content distribution package in addition to text and image content, such as harmonious multimodal experiences and performant content that leverages content insights from user's data and content. According to some aspects, the data processing system includes a comprehensive user experience management suite for planning, execution, and analysis to execute personalization-at-scale strategies. According to some aspects, the data processing system integrates workflows for experience creation and delivery so that there is no need for a content provider to employ another system.

According to some aspects, the data processing system assists with an ideation, definition, expansion, and refinement of an audience for the content distribution campaign. For example, in some cases, the machine learning model qualifies and quantifies the audience using summary statistics and described traits of the audience along with projected performance of the audience towards the content distribution objective of the content provider.

According to some aspects, the data processing system employs at least one of the user experience platform and the machine learning model to generate a complete content distribution campaign, including a program, messaging, content, and journey, or a combination thereof. For example, in some cases, the data processing system optimizes the content distribution campaign for a target audience to meet the content distribution objective of the content provider.

According to some aspects, the data processing system infuses capabilities of the machine learning model with capabilities of the user experience cloud to provide a multimodal conversational interface capable of brainstorming, ideation, and reasoning, that retains and adapts to context. In some cases, the conversational interface is implemented as a copilot for user experience management.

According to some aspects, the data processing system is directed by additional inputs and/or dimensions to dynamically and continuously regenerate generated outputs. According to some aspects, journeys, journey simulation, and performance predictions are based on historical journey data of a content provider combined with external journey data leveraged by the machine learning model.

Accordingly, in some cases, the data processing system provides a content provider with efficiency, efficacy, scale, agility, velocity, ideation, collaboration, and/or execution, thereby allowing the content provider to do more with less.

### Data Processing System

A system and an apparatus for data clustering is described with reference to FIGS. 1-4. One or more aspects of the system and the apparatus include at least one processor; at least one memory storing instructions executable by the at least one processor; a machine learning model including parameters stored in the at least one memory and trained to generate a structured query for a database of users based on a prompt; and a user experience platform configured to generate a user segment of the users based on the structured query. In some aspects, the machine learning model comprises a large language model. In some aspects, the machine learning model comprises a transformer.

In some aspects, the machine learning model is further trained to generate a label of the user segment. In some aspects, the label is based on one or more attributes of the user segment.

In some aspects, the machine learning model is further trained to generate one or more summary statistics of the user segment. In some aspects, the machine learning model is further trained to generate a response to a query about the user segment. In some aspects, the machine learning model is further trained to generate a behavioral prediction for the user segment.

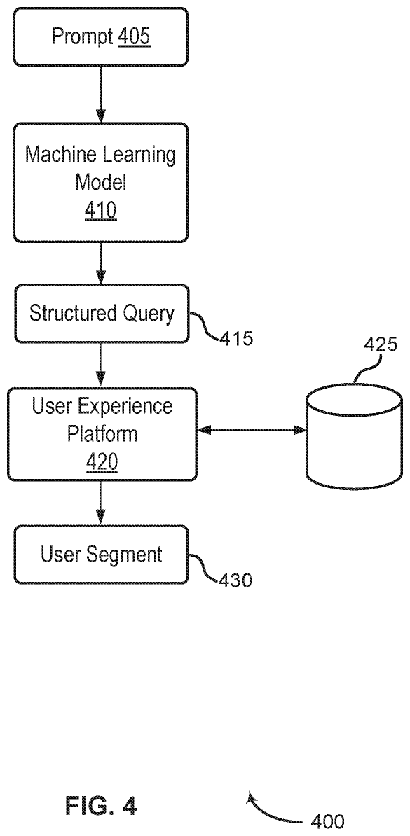

FIG. 1 shows an example of a data processing system 100 according to aspects of the present disclosure. The example shown includes content provider 105, content provider device 110, data processing apparatus 115, cloud 120, and database 125. Data processing system 100 is an example of, or includes aspects of, the corresponding element described with reference to FIG. 4.

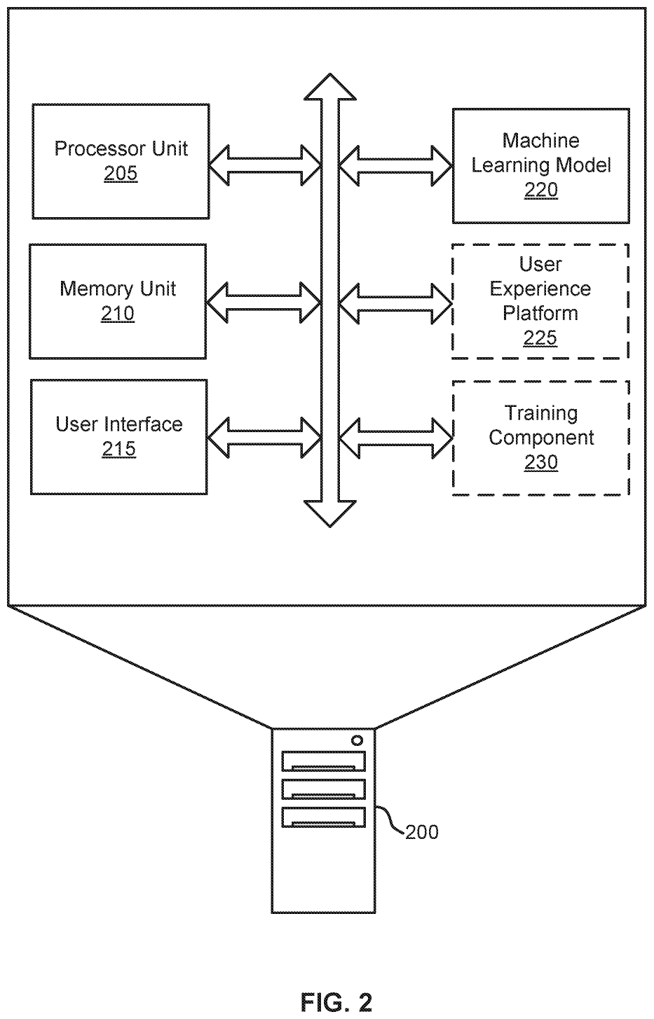

In the example of FIG. 1, content provider 105 provides a text input (e.g., “What audiences travel solo?”) to data processing apparatus 115 via a user interface (e.g., a graphical user interface) provided on content provider device 110 by data processing apparatus 115. Data processing apparatus 115 generates a prompt based on the text input. A machine learning model of data processing apparatus 115 (such as the machine learning model described with reference to FIGS. 2 and 4) generates a structured query based on the prompt. A user experience platform of data processing apparatus 115 (such as the user experience platform described with reference to FIGS. 2 and 4) generates a user segment based on the structured query (for example, by retrieving a list of user identifiers for users corresponding to the structured query from database 125). Data processing apparatus 115 provides an identification of the user segment (and, in some cases and as shown, a description of the user segment generated by the machine learning model) to content provider 105 via the user interface.

According to some aspects, content provider device 110 is a personal computer, laptop computer, mainframe computer, palmtop computer, personal assistant, mobile device, or any other suitable processing apparatus. In some examples, content provider device 110 includes software that displays the user interface (e.g., the graphical user interface) provided by data processing apparatus 115. In some aspects, the user interface allows information (such as text, an image, etc.) to be communicated between content provider 105 and data processing apparatus 115.

According to some aspects, a content provider device user interface enables content provider 105 to interact with content provider device 110. In some embodiments, the content provider device user interface includes an audio device, such as an external speaker system, an external display device such as a display screen, or an input device (e.g., a remote-control device interfaced with the user interface directly or through an I/O controller module). In some cases, the content provider device user interface is a graphical user interface.

Data processing apparatus 115 is an example of, or includes aspects of, the corresponding element described with reference to FIG. 2. According to some aspects, data processing apparatus 115 includes a computer-implemented network. In some embodiments, the computer-implemented network includes a machine learning model (such as the machine learning model described with reference to FIGS. 2 and 4). In some embodiments, data processing apparatus 115 also includes one or more processors, a memory subsystem, a communication interface, an I/O interface, one or more user interface components, and a bus. Additionally, in some embodiments, data processing apparatus 115 communicates with content provider device 110 and database 125 via cloud 120.

In some cases, data processing apparatus 115 is implemented on a server. A server provides one or more functions to content providers linked by way of one or more of various networks, such as cloud 120. In some cases, the server includes a single microprocessor board, which includes a microprocessor responsible for controlling all aspects of the server. In some cases, the server uses microprocessor and protocols to exchange data with other devices or content providers on one or more of the networks via one or more of hypertext transfer protocol (HTTP), simple mail transfer protocol (SMTP), file transfer protocol (FTP), and simple network management protocol (SNMP). In some cases, the server is configured to send and receive hypertext markup language (HTML) formatted files (e.g., for displaying web pages). In various embodiments, the server comprises a general-purpose computing device, a personal computer, a laptop computer, a mainframe computer, a supercomputer, or any other suitable processing apparatus.

Further detail regarding the architecture of data processing apparatus 115 is provided with reference to FIGS. 2-4. Further detail regarding a process for data clustering is provided with reference to FIGS. 5-8. Further detail regarding a process for training a machine learning model is provided with reference to FIG. 9.

Cloud 120 is a computer network configured to provide on-demand availability of computer system resources, such as data storage and computing power. In some examples, cloud 120 provides resources without active management by a content provider. The term “cloud” is sometimes used to describe data centers available to many content providers over the Internet.

Some large cloud networks have functions distributed over multiple locations from central servers. A server is designated an edge server if it has a direct or close connection to a content provider. In some cases, cloud 120 is limited to a single organization. In other examples, cloud 120 is available to many organizations.

In one example, cloud 120 includes a multi-layer communications network comprising multiple edge routers and core routers. In another example, cloud 120 is based on a local collection of switches in a single physical location. According to some aspects, cloud 120 provides communications between content provider device 110, data processing apparatus 115, and database 125.

Database 125 is an example of, or includes aspects of, the corresponding element described with reference to FIG. 4. Database 125 is an organized collection of data. In an example, database 125 stores data in a specified format known as a schema. According to some aspects, database 125 is structured as a single database, a distributed database, multiple distributed databases, or an emergency backup database. In some cases, a database controller manages data storage and processing in database 125 via manual interaction or automatically without manual interaction. According to some aspects, database 125 is external to data processing apparatus 115 and communicates with data processing apparatus 115 via cloud 120. According to some aspects, database 125 is included in data processing apparatus 115.

FIG. 2 shows an example of a data processing apparatus 200 according to aspects of the present disclosure. Data processing apparatus 200 is an example of, or includes aspects of, the corresponding element described with reference to FIG. 1. In one aspect, data processing apparatus 200 includes processor unit 205, memory unit 210, user interface 215, machine learning model 220, user experience platform 225, and training component 230.

Processor unit 205 includes one or more processors. A processor is an intelligent hardware device, such as a general-purpose processing component, a digital signal processor (DSP), a central processing unit (CPU), a graphics processing unit (GPU), a microcontroller, an application specific integrated circuit (ASIC), a field programmable gate array (FPGA), a programmable logic device, a discrete gate or transistor logic component, a discrete hardware component, or any combination thereof.

In some cases, processor unit 205 is configured to operate a memory array using a memory controller. In other cases, a memory controller is integrated into processor unit 205. In some cases, processor unit 205 is configured to execute computer-readable instructions stored in memory unit 210 to perform various functions. In some aspects, processor unit 205 includes special purpose components for modem processing, baseband processing, digital signal processing, or transmission processing.

Memory unit 210 includes one or more memory devices. Examples of a memory device include random access memory (RAM), read-only memory (ROM), or a hard disk. Examples of memory devices include solid state memory and a hard disk drive. In some examples, memory is used to store computer-readable, computer-executable software including instructions that, when executed, cause at least one processor of processor unit 205 to perform various functions described herein.

In some cases, memory unit 210 includes a basic input/output system (BIOS) that controls basic hardware or software operations, such as an interaction with peripheral components or devices. In some cases, memory unit 210 includes a memory controller that operates memory cells of memory unit 210. For example, in some cases, the memory controller includes a row decoder, column decoder, or both. In some cases, memory cells within memory unit 210 store information in the form of a logical state.

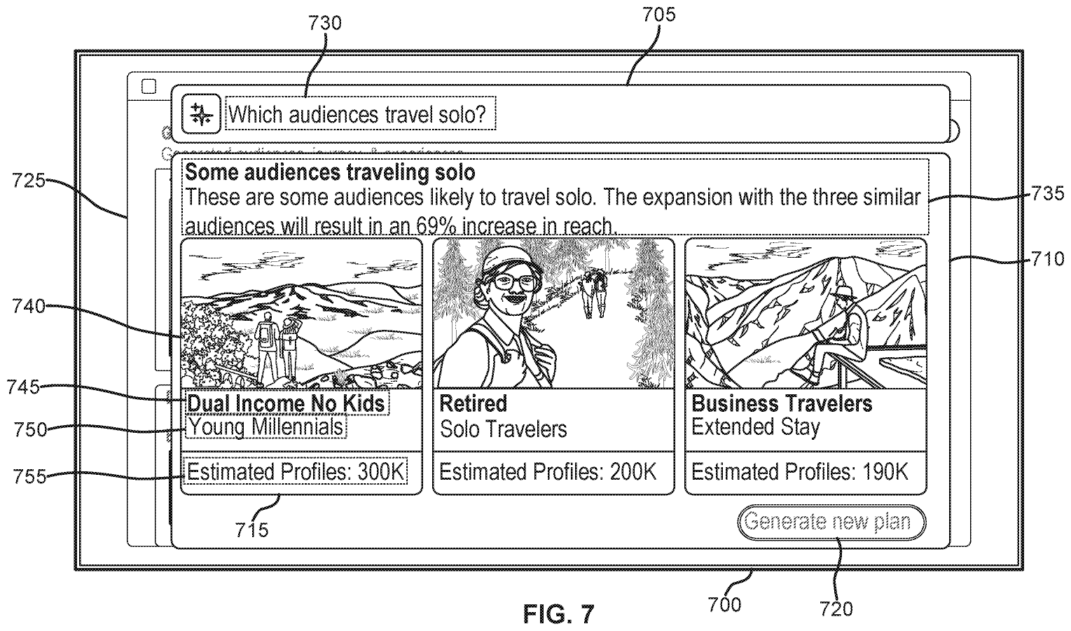

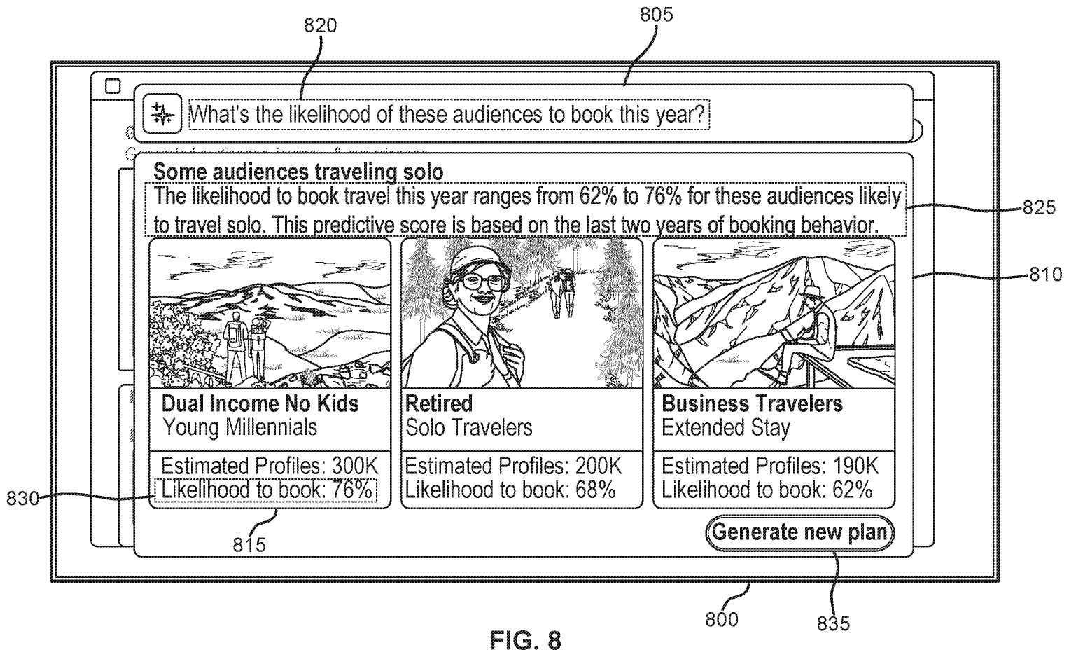

User interface 215 is an example of, or includes aspects of, the corresponding element described with reference to FIGS. 7-8. According to some aspects, user interface 215 provides for communication between a content provider device (such as the content provider device described with reference to FIG. 1) and data processing apparatus 200. For example, in some cases, user interface 215 is a graphical user interface (GUI) provided on the content provider device by data processing apparatus 200.

According to some aspects, user interface 215 receives a content provider input. In some cases, the content provider input is a text input. In some examples, user interface 215 receives an additional content provider input. In some examples, user interface 215 receives a query about the user segment.

Machine learning model 220 is an example of, or includes aspects of, the corresponding element described with reference to FIG. 4. According to some aspects, machine learning model 220 is implemented as software stored in memory unit 210 and executable by processor unit 205, as firmware, as one or more hardware circuits, or as a combination thereof. In some cases, machine learning model 220 is included in user experience platform 225. According to some aspects, machine learning model 220 comprises one or more artificial neural networks (ANNs) designed and/or trained to generate text (such as a structured query for a database of users based on the prompt).

An ANN is a hardware component or a software component that includes a number of connected nodes (i.e., artificial neurons) that loosely correspond to the neurons in a human brain. Each connection, or edge, transmits a signal from one node to another (like the physical synapses in a brain). When a node receives a signal, it processes the signal and then transmits the processed signal to other connected nodes.

In some cases, the signals between nodes comprise real numbers, and the output of each node is computed by a function of the sum of its inputs. In some examples, nodes determine their output using other mathematical algorithms, such as selecting the max from the inputs as the output, or any other suitable algorithm for activating the node. Each node and edge are associated with one or more node weights that determine how the signal is processed and transmitted.

In ANNs, a hidden (or intermediate) layer includes hidden nodes and is located between an input layer and an output layer. Hidden layers perform nonlinear transformations of inputs entered into the network. Each hidden layer is trained to produce a defined output that contributes to a joint output of the output layer of the ANN. Hidden representations are machine-readable data representations of an input that are learned from hidden layers of the ANN and are produced by the output layer. As the understanding of the ANN of the input improves as the ANN is trained, the hidden representation is progressively differentiated from earlier iterations.

During a training process of an ANN, the node weights are adjusted to improve the accuracy of the result (i.e., by minimizing a loss which corresponds in some way to the difference between the current result and the target result). The weight of an edge increases or decreases the strength of the signal transmitted between nodes. In some cases, nodes have a threshold below which a signal is not transmitted at all. In some examples, the nodes are aggregated into layers. Different layers perform different transformations on their inputs. The initial layer is known as the input layer and the last layer is known as the output layer. In some cases, signals traverse certain layers multiple times.

According to some aspects, machine learning model 220 includes machine learning parameters stored in memory unit 210. Machine learning parameters are variables that provide a behavior and characteristics of a machine learning model. In some cases, machine learning parameters are learned or estimated from training data and are used to make predictions or perform tasks based on learned patterns and relationships in the data.

In some cases, machine learning parameters are adjusted during a training process to minimize a loss function or to maximize a performance metric. The goal of the training process is to find optimal values for the parameters that allow the machine learning model to make accurate predictions or perform well on a given task.

For example, during the training process, an algorithm adjusts machine learning parameters to minimize an error or loss between predicted outputs and actual targets according to optimization techniques like gradient descent, stochastic gradient descent, or other optimization algorithms. Once the machine learning parameters are learned from the training data, the machine learning parameters are used to make predictions on new, unseen data.

In some cases, parameters of an ANN include weights and biases associated with each neuron in the ANN that control a strength of connections between neurons and influence the ability of the ANN to capture complex patterns in data.

According to some aspects, machine learning model 220 comprises a large language model. A large language model is machine learning model that is designed and/or trained to learn statistical patterns and structures of human language. Large language models are capable of a wide range of language-related tasks such as text completion, question answering, translation, summarization, and creative writing, in response to a prompt. In some cases, the term “large” refers to a size and complexity of the large language model, usually measured in terms of a number of parameters of the large language model, where more parameters allow a large language model to understand more intricate language patterns and generate more nuanced and coherent text.

In some cases, the large language model comprises a sequence-to-sequence (seq2seq) model. A seq2seq model comprises one or more ANNs configured to transform a given sequence of elements, such as a sequence of words in a sentence, into another sequence using sequence transformation.

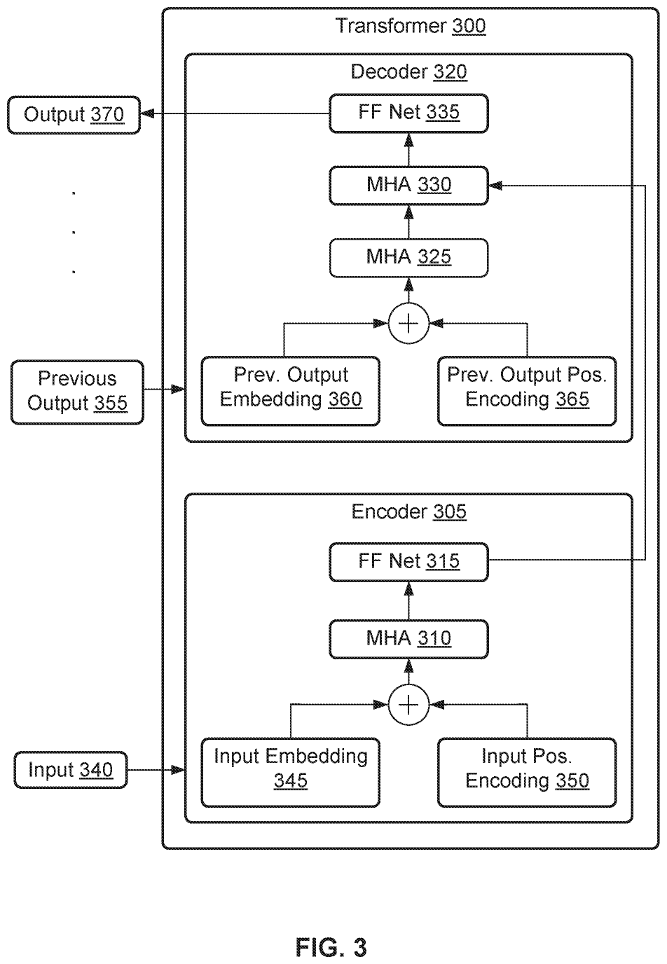

In some cases, machine learning model 220 comprises one or more transformers (such as the transformer described with reference to FIG. 3). In some cases, a transformer comprises one or more ANNs comprising attention mechanisms that enable the transformer to weigh an importance of different words or tokens within a sequence. In some cases, a transformer processes entire sequences simultaneously in parallel, making the transformer highly efficient and allowing the transformer to capture long-range dependencies more effectively.

In some cases, a transformer comprises an encoder-decoder structure. In some cases, the encoder of the transformer processes an input sequence and encodes the input sequence into a set of high-dimensional representations. In some cases, the decoder of the transformer generates an output sequence based on the encoded representations and previously generated tokens. In some cases, the encoder and the decoder are composed of multiple layers of self-attention mechanisms and feed-forward ANNs.

In some cases, the self-attention mechanism allows the transformer to focus on different parts of an input sequence while computing representations for the input sequence. In some cases, the self-attention mechanism captures relationships between words of a sequence by assigning attention weights to each word based on a relevance to other words in the sequence, thereby enabling the transformer to model dependencies regardless of a distance between words.

An attention mechanism is a key component in some ANN architectures, particularly ANNs employed in natural language processing (NLP) and sequence-to-sequence tasks, that allows an ANN to focus on different parts of an input sequence when making predictions or generating output.

NLP refers to techniques for using computers to interpret or generate natural language. In some cases, NLP tasks involve assigning annotation data such as grammatical information to words or phrases within a natural language expression. Different classes of machine-learning algorithms have been applied to NLP tasks. Some algorithms, such as decision trees, utilize hard if-then rules. Other systems use neural networks or statistical models which make soft, probabilistic decisions based on attaching real-valued weights to input features. In some cases, these models express the relative probability of multiple answers.

Some sequence models (such as recurrent neural networks) process an input sequence sequentially, maintaining an internal hidden state that captures information from previous steps. However, in some cases, this sequential processing leads to difficulties in capturing long-range dependencies or attending to specific parts of the input sequence.

The attention mechanism addresses these difficulties by enabling an ANN to selectively focus on different parts of an input sequence, assigning varying degrees of importance or attention to each part. The attention mechanism achieves the selective focus by considering a relevance of each input element with respect to a current state of the ANN.

In some cases, an ANN employing an attention mechanism receives an input sequence and maintains its current state, which represents an understanding or context. For each element in the input sequence, the attention mechanism computes an attention score that indicates the importance or relevance of that element given the current state. The attention scores are transformed into attention weights through a normalization process, such as applying a softmax function. The attention weights represent the contribution of each input element to the overall attention. The attention weights are used to compute a weighted sum of the input elements, resulting in a context vector. The context vector represents the attended information or the part of the input sequence that the ANN considers most relevant for the current step. The context vector is combined with the current state of the ANN, providing additional information and influencing subsequent predictions or decisions of the ANN.

In some cases, by incorporating an attention mechanism, an ANN dynamically allocates attention to different parts of the input sequence, allowing the ANN to focus on relevant information and capture dependencies across longer distances.

In some cases, calculating attention involves three basic steps. First, a similarity between a query vector Q and a key vector K obtained from the input is computed to generate attention weights. In some cases, similarity functions used for this process include dot product, splice, detector, and the like. Next, a softmax function is used to normalize the attention weights. Finally, the attention weights are weighed together with their corresponding values V. In the context of an attention network, the key K and value V are typically vectors or matrices that are used to represent the input data. The key K is used to determine which parts of the input the attention mechanism should focus on, while the value V is used to represent the actual data being processed.

According to some aspects, machine learning model 220 receives the prompt. According to some aspects, machine learning model 220 generates a structured query for a database of users based on the prompt. In some examples, machine learning model 220 generates a label of the user segment. In some examples, machine learning model 220 identifies one or more attributes of the user segment, where the label is based on the one or more attributes. In some examples, machine learning model 220 generates one or more summary statistics of the user segment. In some examples, machine learning model 220 generates a response to a query. In some examples, machine learning model 220 generates a behavioral prediction for the user segment. In some examples, machine learning model 220 receives an additional prompt.

User experience platform 225 is an example of, or includes aspects of, the corresponding element described with reference to FIG. 4. According to some aspects, user experience platform 225 is implemented as software stored in memory unit 210 and executable by processor unit 205, as firmware, as one or more hardware circuits, or as a combination thereof.

According to some aspects, user experience platform 225 is omitted from data processing apparatus 200 and is implemented in at least one apparatus separate from data processing apparatus 200 (for example, at least one apparatus comprised in a cloud, such as the cloud described with reference to FIG. 1). According to some aspects, the separate apparatus comprising user experience platform 225 communicates with data processing apparatus 200 (for example, via the cloud) to perform the functions of user experience platform 225 described herein.

For example, in some cases, data processing apparatus 200 is implemented as an edge server in a data processing system (such as the content generation system described with reference to FIGS. 1 and 4), user experience platform 225 is included in a central server of the data processing system, and data processing apparatus 200 communicates with the central server to implement the functions of user experience platform 225 described herein.

According to some aspects, user experience platform 225 includes a set of creative, analytics, social, advertising, media optimization, targeting, Web experience management, journey orchestration and content management tools. In some cases, user experience platform 225 includes one or more of a graphic design component providing image generation and/or editing capabilities, a video editing component, a web development component, and a photography component. In some cases, user experience platform 225 comprises one or more of an enterprise content management component; a digital asset management component; an enterprise content distribution component that manages direct content distribution campaigns, leads, resources, user data, and analytics, and allows content providers to design and orchestrate targeted and personalized campaigns via channels such as direct mail, e-mail, SMS, and MMS; a data management component for data modeling and predictive analytics; and a web analytics system that provides web metrics, dimensions, and allows content provider to define tags implemented in webpage for web tracking to provide customized dimensions, metrics, segmentations, content provider reports, and dashboards.

In some cases, user experience platform 225 has comprehensive end-to-end capabilities with content distribution-specific technology across conceptualization, execution, and insights to merge with machine learning model 220 and generative machine learning experiences. In some cases, user experience platform 225 builds a cohesive user view, supporting but not limited to analytics, digital advertising, email, user data management, social media, call centers, and commerce. In some cases, user experience platform 225 consolidates, identifies, and builds full profiles from datasets that provide differentiating data for generating content that benefits from personalization.

According to some aspects, user experience platform 225 comprises one or more ANNs, and one or more components of user experience platform 225 are implemented via the one or more ANNs.

According to some aspects, user experience platform 225 generates a user segment of the users based on the structured query. In some examples, user experience platform 225 identifies a data trend, where the prompt is based on the data trend. According to some aspects, user experience platform 225 generates the prompt. According to some aspects, user experience platform 225 generates the additional prompt. In some examples, user experience platform 225 modifies the user segment based on the additional prompt.

According to some aspects, training component 230 is implemented as software stored in memory unit 210 and executable by processor unit 205, as firmware, as one or more hardware circuits, or as a combination thereof. According to some aspects, training component 230 is omitted from data processing apparatus 200 and is implemented in at least one apparatus separate from data processing apparatus 200 (for example, at least one apparatus comprised in a cloud, such as the cloud described with reference to FIG. 1). According to some aspects, the separate apparatus comprising training component 230 communicates with data processing apparatus 200 (for example, via the cloud) to perform the functions of training component 230 described herein.

According to some aspects, training component 230 obtains training data that includes a training prompt and a ground-truth structured query. In some examples, training component 230 trains machine learning model 220 to generate structured queries for a database of users using the training data. In some examples, training component 230 trains machine learning model 220 to generate a label for a user segment from the database of users. In some examples, training component 230 trains machine learning model 220 to generate a behavioral prediction for the user segment. According to some aspects, training component 230 trains machine learning model 220 to generate one or more summary statistics for a user segment from the database of users.

FIG. 3 shows an example of a transformer 300 according to aspects of the present disclosure. The example shown includes transformer 300, encoder 305, decoder 320, input 340, input embedding 345, input positional encoding 350, previous output 355, previous output embedding 360, previous output positional encoding 365, and output 370.

In some cases, encoder 305 includes multi-head self-attention sublayer 310 and feed-forward network sublayer 315. In some cases, decoder 320 includes first multi-head self-attention sublayer 325, second multi-head self-attention sublayer 330, and feed-forward network sublayer 335.

According to some aspects, a machine learning model (such as the machine learning model described with reference to FIGS. 2 and 4) comprises transformer 300. In some cases, encoder 305 is configured to map input 340 (for example, a sequence of words or tokens, such as a prompt as described herein) to a sequence of continuous representations that are fed into decoder 320. In some cases, decoder 320 generates output 370 (e.g., a predicted sequence of words or tokens) based on the output of encoder 305 and previous output 355 (e.g., a previously predicted output sequence), which allows for the use of autoregression.

For example, in some cases, encoder 305 parses input 340 into tokens and vectorizes the parsed tokens to obtain input embedding 345, and adds input positional encoding 350 (e.g., positional encoding vectors for input 340 of a same dimension as input embedding 345) to input embedding 345. In some cases, input positional encoding 350 includes information about relative positions of words or tokens in input 340.

In some cases, encoder 305 comprises one or more encoding layers (e.g., six encoding layers) that generate contextualized token representations, where each representation corresponds to a token that combines information from other input tokens via self-attention mechanism. In some cases, each encoding layer of encoder 305 comprises a multi-head self-attention sublayer (e.g., multi-head self-attention sublayer 310). In some cases, the multi-head self-attention sublayer implements a multi-head self-attention mechanism that receives different linearly projected versions of queries, keys, and values to produce outputs in parallel. In some cases, each encoding layer of encoder 305 also includes a fully connected feed-forward network sublayer (e.g., feed-forward network sublayer 315) comprising two linear transformations surrounding a Rectified Linear Unit (ReLU) activation:

$$FFN ( x ) = R e L U ( {W}_{1} x + {b}_{1} ) {W}_{2} + {b}_{2} \qquad ( 1 )$$

In some cases, each layer employs different weight parameters (W₁, W₂) and different bias parameters (b₁, b₂) to apply a same linear transformation each word or token in input 340.

In some cases, each sublayer of encoder 305 is followed by a normalization layer that normalizes a sum computed between a sublayer input x and an output sublayer(x) generated by the sublayer:

$$layernorm ( x + sublayer ( x ) ) \qquad ( 2 )$$

In some cases, encoder 305 is bidirectional because encoder 305 attends to each word or token in input 340 regardless of a position of the word or token in input 340.

In some cases, decoder 320 comprises one or more decoding layers (e.g., six decoding layers). In some cases, each decoding layer comprises three sublayers including a first multi-head self-attention sublayer (e.g., first multi-head self-attention sublayer 325), a second multi-head self-attention sublayer (e.g., second multi-head self-attention sublayer 330), and a feed-forward network sublayer (e.g., feed-forward network sublayer 335). In some cases, each sublayer of decoder 320 is followed by a normalization layer that normalizes a sum computed between a sublayer input x and an output sublayer(x) generated by the sublayer.

In some cases, decoder 320 generates previous output embedding 360 of previous output 355 and adds previous output positional encoding 365 (e.g., position information for words or tokens in previous output 355) to previous output embedding 360. In some cases, each first multi-head self-attention sublayer receives the combination of previous output embedding 360 and previous output positional encoding 365 and applies a multi-head self-attention mechanism to the combination. In some cases, for each word in an input sequence, each first multi-head self-attention sublayer of decoder 320 attends only to words preceding the word in the sequence, and so transformer 300's prediction for a word at a particular position only depends on known outputs for a word that came before the word in the sequence. For example, in some cases, each first multi-head self-attention sublayer implements multiple single-attention functions in parallel by introducing a mask over values produced by the scaled multiplication of matrices Q and K by suppressing matrix values that would otherwise correspond to disallowed connections.

In some cases, each second multi-head self-attention sublayer implements a multi-head self-attention mechanism similar to the multi-head self-attention mechanism implemented in each multi-head self-attention sublayer of encoder 305 by receiving a query Q from a previous sublayer of decoder 320 and a key K and a value V from the output of encoder 305, allowing decoder 320 to attend to each word in the input 340.

In some cases, each feed-forward network sublayer implements a fully connected feed-forward network similar to feed-forward network sublayer 315. In some cases, the feed-forward network sublayers are followed by a linear transformation and a softmax to generate a prediction of output 370 (e.g., a prediction of a next word or token in a sequence of words or tokens). Accordingly, in some cases, transformer 300 generates a structured query as described herein based on a predicted sequence of words or tokens.

FIG. 4 shows an example of data flow in a data processing system 400 according to aspects of the present disclosure. The example shown includes prompt 405, machine learning model 410, structured query 415, user experience platform 420, database 425, and user segment 430.

Data processing system 400 is an example of, or includes aspects of, the corresponding element described with reference to FIG. 1. Machine learning model 410 is an example of, or includes aspects of, the corresponding element described with reference to FIG. 2. User experience platform 420 is an example of, or includes aspects of, the corresponding element described with reference to FIG. 2. Database 425 is an example of, or includes aspects of, the corresponding element described with reference to FIG. 1.

Referring to FIG. 4, according to some aspects, machine learning model 410 receives prompt 405. In some cases, user experience platform 420 provides prompt 405 to machine learning model 410. In some cases, a content provider (such as the content provider described with reference to FIG. 1) provides prompt 405 to machine learning model 410 (for example, via a user interface such as the user interface described with reference to FIGS. 2 and 7-8).

According to some aspects, machine learning model 410 generates structured query 415 based on prompt 405. According to some aspects, user experience platform 420 generates user segment 430 based on structured query 415. In some cases, user experience platform 420 generates user segment 430 by retrieving user information from database 425 according to structured query 415.

### Data Clustering

A method for data clustering is described with reference to FIGS. 5-8. One or more aspects of the method include receiving a prompt; generating a structured query for a database of users based on the prompt; and generating a user segment of the users based on the structured query.

Some examples of the method further include identifying a data trend, wherein the prompt is based on the data trend. Some examples of the method further include generating a label of the user segment. Some examples of the method further include identifying one or more attributes of the user segment, wherein the label is based on the one or more attributes.

Some examples of the method further include generating one or more summary statistics of the user segment. Some examples of the method further include receiving an additional prompt. Some examples further include modifying the user segment based on the additional prompt. Some examples of the method further include receiving a query about the user segment. Some examples further include generating a response to the query using the machine learning model. Some examples of the method further include generating a behavioral prediction for the user segment.

FIG. 5 shows an example of a method 500 for querying a database for a user segment according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

Referring to FIG. 5, a data processing system generates a user segment based on a structured query generated by a machine learning model of the data processing system (such as the machine learning model described with reference to FIGS. 2 and 4) and provides information about the user segment to a content provider. In the example of FIG. 5, a content provider provides a content provider input corresponding to a prompt in response to an identification of a data trend or anomaly.

At operation 505, a content provider provides a content provider input to a user interface. In some cases, the operations of this step refer to, or are performed by, a content provider as described with reference to FIG. 1. In an example, a data processing apparatus (such as the data processing apparatus of FIGS. 1 and 2) monitors a set of data using the user experience platform. In some cases, when the user experience platform detects a trend or an anomaly in the data, the data processing apparatus provides information relating to the trend or anomaly via a user interface displayed on a content provider device (such as a content provider device as described with reference to FIG. 1) by the data processing apparatus. In an example, the content provider provides the content provider input (such as a text input or a selection of a user interface element) to the user interface in response to the display of the information on the user interface.

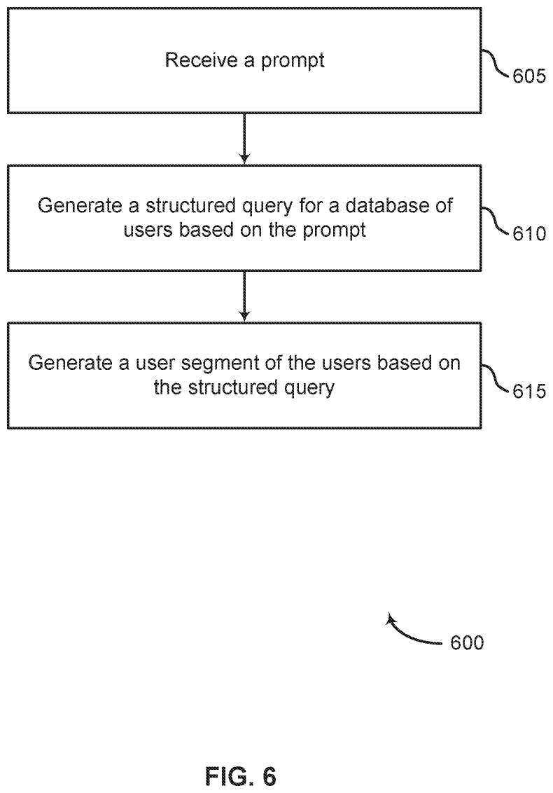

At operation 510, the system generates a structured query based on the content provider input. In some cases, the operations of this step refer to, or are performed by, a data processing apparatus as described with reference to FIGS. 1 and 2. For example, in some cases, a user experience platform of the data processing apparatus (such as the user experience platform described with reference to FIGS. 2 and 4) generates a prompt based on the content provider input as described with reference to FIG. 6, and a machine learning model of the data processing apparatus (such as the machine learning model described with reference to FIGS. 2 and 4) generates a structured query based on the prompt as described with reference to FIG. 6.

At operation 515, the system generates a user segment based on providing the structured query to a database. In some cases, the operations of this step refer to, or are performed by, a data processing apparatus as described with reference to FIGS. 1 and 2. For example, in some cases, the user experience platform generates the user segment by querying a database (such as the database described with reference to FIG. 1) with the structured query as described with reference to FIG. 6.

At operation 520, the system displays information relating to the user segment to the content provider. In some cases, the operations of this step refer to, or are performed by, a data processing apparatus as described with reference to FIGS. 1 and 2. For example, in some cases, the user interface displays one or more of a label for the user segment, a description of the user segment, summary statistics for the user segment, and an evaluation of a likelihood of a member of the user segment to perform an action to the content provider as described with reference to FIG. 6.

FIG. 6 shows an example of a method 600 for generating a user segment according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

Referring to FIG. 6, a data processing apparatus (such as the data processing apparatus described with reference to FIGS. 1-2) generates a user segment based on a prompt using a structured query provided by a machine learning model of the data processing apparatus (such as the machine learning model described with reference to FIGS. 2 and 4) and provides information about the user segment to a content provider.

In some cases, the machine learning model understands semantics of a data trend or anomaly identified by a user experience platform of the data processing system (such as the user experience platform described with reference to FIGS. 2 and 4) and, in response to a prompt relating to the data trend or anomaly, translates the semantics into a structured query.

In some cases, the user experience platform generates a user segment by running the structured query against a database of users (such as the database described with reference to FIGS. 1 and 4) to identify a group of user identifiers that correspond to user profiles that match the structured query.

In some cases, the machine learning model receives the user profiles of the user segment as input. In some cases, the machine learning model generates a description of one or more descriptive characteristics of the user segment (e.g., “eco-friendly”, etc.) based on the user profiles. In some cases, the machine learning model generates one or more summary statistics, such as a number of profiles, demographic information, etc., for the user segment based on the user profiles.

In some cases, based on the user profiles, the machine learning model generates an evaluation of a likelihood of the user segment to perform an action toward an objective (in some cases, provided as input by the user experience platform to the machine learning model based on content provider information available to the user experience platform), such as a probability of a member of the user segment making a purchase within a certain timeframe. In some cases, the user experience platform displays one or more of the description of the user segment, the summary statistics for the user segment, and the evaluation to the content provider.

At operation 605, the system receives a prompt. In some cases, the operations of this step refer to, or are performed by, a machine learning model as described with reference to FIGS. 2 and 4. In some cases, a user experience platform (such as the user experience platform described with reference to FIGS. 2 and 4) generates the prompt. In some cases, the prompt includes contextual information relating to one or more of a content provider (such as content provider information corresponding to one or more of a content provider profile, a content distribution campaign focus, an objective of the content provider, and/or historical content distribution campaign performances for the content provider), information displayed on a user interface (such as the user interface described with reference to FIGS. 2 and 7-8), detection of information (such as a detected data trend or anomaly in data monitored by the user experience platform), a selection of a user interface element. In some cases, the user experience platform communicates with one or more of the user interface and a database (such as the database described with reference to FIG. 1) to obtain the contextual information.

In some cases, the user experience platform generates the prompt in response to the detection of the information. In some cases, the user experience platform generates the prompt in response to a content provider input provided to the user interface. For example, in some cases, the user interface displays an element suggesting that a user segment be identified based on the detection of the information, and the content provider provides the content provider input to the element. In some cases, the content provider provides a text input (e.g., “identify a relevant user segment”) to a text input element of the user interface, and the user experience platform generates the prompt in response to the text input. In some cases, the prompt includes the text input. An example of a text input and a text input element for accepting the text input is described with reference to FIG. 7.

At operation 610, the system generates a structured query for a database of users based on the prompt. In some cases, the operations of this step refer to, or are performed by, a machine learning model as described with reference to FIGS. 2 and 4. For example, in some cases, the user experience platform provides the prompt to the machine learning model. In some cases, according to the prompt, the machine learning model translates semantics of the data included in the prompt to generate the structured query. For example, in some cases, the machine learning model includes a large language model trained to generate the structured query based on the prompt. In some cases, the machine learning model includes one or more transformers trained to generate the structured query based on the prompt.

In some cases, the machine learning model generates a label for the user segment based on the prompt. For example, in some cases, the machine learning model identifies one or more attributes of the user segment by inferring the one or more attributes based on the prompt, and generates the label based on the one or more attributes. For example, in some cases, the machine learning model generates the label based on semantic affiliations among user profiles of the user segment.

In some cases, the machine learning model generates a summary statement based on the prompt. In some cases, the summary statement comprises a natural language statement summarizing one or more user segments that the machine learning model determines to correspond to the prompt. In some cases, the summary statement comprises a statement regarding an expected outcome related to the one or more user segments.

In some cases, the machine learning model generates one or more summary statistics, such as a number of profiles, demographic information, etc., for the user segment based on the prompt.

In some cases, the machine learning model generates a description of one or more descriptive characteristics of the user segment based on the prompt. In some cases, the machine learning model infers the descriptive characteristic based on an understanding of semantic information included in the prompt.

At operation 615, the system generates a user segment of the users based on the structured query. In some cases, the operations of this step refer to, or are performed by, a user experience platform as described with reference to FIGS. 2 and 4.

For example, in some cases, the user experience platform receives the structured query from the machine learning model and provides the structured query to a database storing a set of user profiles (such as the database described with reference to FIG. 1). In some cases, in response to providing the structured query to the database, the user experience platform receives one or more user identifiers respectively corresponding to one or more user profiles that match the structured query. In some cases, the user experience platform generates a user segment by including each of the user identifiers received from the database in the user segment.

According to some aspects, the data processing apparatus displays information relating to the user segment to the content provider. For example, in some cases, the user experience platform retrieves the user profiles corresponding to the user segment from the database and provides the user profiles to the machine learning model. In some cases, the machine learning model generates information based on the user profiles.

In some cases, the user interface displays the summary statement. An example of a summary statement is described with reference to FIG. 7. In some cases, the user interface displays the label for the user segment. An example of a label for a user segment is described with reference to FIG. 7. In some cases, the user interface displays the descriptive characteristics of the user segment. An example of a descriptive characteristic is described with reference to FIG. 7. In some cases, the user interface displays the summary statistics of the user segment. An example of summary statistics is described with reference to FIG. 7.

According to some aspects, the machine learning model receives an additional prompt. For example, in some cases, the user experience platform generates the additional prompt in response to a content provider input (e.g., a text input or a selection of an appropriate user interface element) indicating that the user segment should be adjusted or refined or that a new user segment should be generated. In some cases, the machine learning model generates an additional structured query based on the additional prompt. In some cases, the user experience platform retrieves one or more additional user identifiers from the database corresponding to the additional structured query. In some cases, the user experience platform modifies the user segment based on the additional user identifier.

According to some aspects, the user interface receives a query about the user segment. In some cases, the query comprises a natural language question. In some cases, the content provider provides the query. In some cases, the content provider provides the query to a text input element displayed by the user interface. Examples of a text input element and a query are described with reference to FIG. 8.

According to some aspects, the user experience platform generates a query prompt including the query and contextual information. According to some aspects, the machine learning model generates a response to the query based on the query prompt. In some cases, the response comprises a natural language statement. In some cases, the response comprises code or instructions (such as a macro) for the user experience platform to execute to retrieve, generate, and/or display content. In some cases, the user interface displays the response to the query. An example of a response to the query is described with reference to FIG. 8.

According to some aspects, the machine learning model generates a behavioral prediction for the user segment. In some cases, one or more ANNs of the user experience platform generate the behavioral prediction for the user segment, and the machine learning model generates a text description of the behavioral prediction provided by the one or more ANNs. In some cases, the behavioral prediction comprises a natural language statement of a likelihood that one or more members of the user segment will perform an action. In some cases, the user interface displays the behavioral prediction. An example of a behavioral prediction is described with reference to FIG. 8.

According to some aspects, the data processing system customizes content based on the user segment. For example, in some cases, the data processing system generates and/or retrieves content relating to the user segment using one or more of the machine learning model and the user experience platform. According to some aspects, the data processing system provides the customized content to one or more users of the user segment.

FIG. 7 shows an example of a user interface for determining a user segment according to aspects of the present disclosure. The example shown includes user interface 700, text input 730, user segment summary statement 735, visual element 740, user segment label 745, user segment descriptive characteristic 750, and user segment summary statistic 755.

User interface 700 is an example of, or includes aspects of, the corresponding element described with reference to FIGS. 2 and 8. In one aspect, user interface 700 includes text input element 705, main element 710, generate new plan element 720, and backgrounded element 725.

Text input element is an example of, or includes aspects of, the corresponding element described with reference to FIG. 8. Main element 710 is an example of, or includes aspects of, the corresponding element described with reference to FIG. 8. In one aspect, main element 710 includes segment element 715. Segment element 715 is an example of, or includes aspects of, the corresponding element described with reference to FIG. 8.

Generate new plan element 720 is an example of, or includes aspects of, the corresponding element described with reference to FIG. 8. Text input 730 is an example of, or includes aspects of, the corresponding element described with reference to FIG. 4.

In the example of FIG. 7, user interface 700 has displayed information to a content provider relating to a data trend of an increase in solo travelers (for example, in backgrounded element 725 displayed underneath main element 710, previously foregrounded). The content provider provides text input 730 (“Which audiences travel solo?”) to text input element 705. In some cases, text input element 705 is displayed in response to a content provider interaction with backgrounded element 725.

In some cases, as described with reference to FIG. 6, a user experience platform generates a prompt based on text input 730, a machine learning model generates a structured query, user segment summary statement 735, user segment label 745, user segment descriptive characteristic 750, and user segment summary statistic 755 based on the prompt, and the user experience platform generates a user segment based on the structured query and generates or retrieves visual element 740 based on instructions generated by the machine learning model.

In the example of FIG. 7, main element 710 displays user segment summary statement 735 generated by the machine learning model. In the example of FIG. 7, user segment summary statement 735 includes a natural language statement summarizing three user segments “Dual Income No Kids”, “Retired”, and “Business Travelers” identified and labeled based on the prompt.

In the example of FIG. 7, segment element 715 displays visual element 740, user segment label 745, user segment descriptive characteristic 750, and user segment summary statistic 755 corresponding to the “Dual Income No Kids” user segment.

As shown in FIG. 7, user segment label 745 includes an identification of a first user segment as including user profiles corresponding to data relating to Dual Income No Kids, user segment descriptive characteristic 750 includes a statement that is broadly descriptive of an attribute of the Dual Incomes No Kids user segment (“Young Millennials”), and user segment summary statistic 755 includes a statement of an estimated number of user profiles included in the Dual Income No Kids user segment.

In some cases, the data processing apparatus is configured to generate information (such as a content distribution campaign plan) in response to a content provider selection of one or more elements corresponding to one or more user segments. For example, as shown in FIG. 7, a content provider interacts with generate new plan element 720 to generate a new content distribution campaign plan. In the example of FIG. 7, the generate new plan element 720 is greyed out because the content provider has not yet selected one or more user segments to generate a plan for.

FIG. 8 shows an example of a user interface for a query according to aspects of the present disclosure. The example shown includes user interface 800, query 820, response 825, and behavioral prediction 830. In one aspect, user interface 800 includes text input element 805, main element 810, user segment element 815, and generate new plan element 835. User interface 800 is an example of, or includes aspects of, the corresponding element described with reference to FIGS. 2 and 7. Text input element, main element 810, user segment element 815, and generate new plan element 835 are examples of, or include aspects of, the corresponding elements described with reference to FIG. 7. A repeated description of similar elements described with reference to FIG. 7 is omitted.

Referring to FIG. 8, user interface 800 displays text input element 805 in response to displaying information relating to one or more user segments. A content provider (such as the content provider described with reference to FIG. 1) provides query 820 (“What's the likelihood of these audiences to book this year?”) to text input element 805.

As shown in FIG. 8, main element 810 displays response 825 generated by a machine learning model in response to query 820 as described with reference to FIG. 6. In the example of FIG. 8, response 825 includes a natural language statement answering query 820. As shown in FIG. 8, user segment element 815 displays behavioral prediction 830 (“Likelihood to book: 76%”) generated by the machine learning model. As shown in FIG. 8, generate new plan element 835 includes bold black text indicating that a new plan can be generated because the content provider has selected an element corresponding to one or more of the user segments.

### Training

A method for data clustering is described with reference to FIG. 9. One or more aspects of the method include obtaining training data that includes a training prompt and a ground-truth structured query and training a machine learning model to generate structured queries for a database of users using the training data.

Some examples of the method further include training the machine learning model to generate a label for a user segment from the database of users. Some examples of the method further include training the machine learning model to generate one or more summary statistics for a user segment from the database of users. Some examples of the method further include training the machine learning model to generate a behavioral prediction for the user segment.

FIG. 9 shows an example of a method 900 for training a machine learning model according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

At operation 905, the system obtains training data that includes a training prompt and a ground-truth structured query. In some cases, the operations of this step refer to, or are performed by, a training component as described with reference to FIG. 2. For example, in some cases, the training prompt is a prompt as described herein, and the ground-truth structured query is a structured query as described herein. In some cases, the training component obtains the training data from a database (such as the database described with reference to FIG. 1) or from another data source (such as the Internet).

At operation 910, the system trains a machine learning model to generate structured queries for a database of users using the training data. In some cases, the operations of this step refer to, or are performed by, a training component as described with reference to FIG. 2.

For example, in some cases, the training component provides the training prompt to a machine learning model (such as the machine learning model described with reference to FIGS. 2 and 4). In some cases, the machine learning model generates a structured query based on the training prompt as described with reference to FIG. 6. In some cases, the training component compares the structured query to the ground-truth structured query to determine a loss function.

The term “loss function” refers to a function that impacts how a machine learning model is trained in a supervised learning model. For example, during each training iteration, the output of the machine learning model is compared to the known annotation information in the training data. The loss function provides a value (a “loss”) for how close the predicted annotation data is to the actual annotation data. After computing the loss, the parameters of the model are updated accordingly and a new set of predictions are made during the next iteration.

Supervised learning is one of three basic machine learning paradigms, alongside unsupervised learning and reinforcement learning. Supervised learning is a machine learning technique based on learning a function that maps an input to an output based on example input-output pairs. Supervised learning generates a function for predicting labeled data based on labeled training data consisting of a set of training examples. In some cases, each example is a pair consisting of an input object (typically a vector) and a desired output value (i.e., a single value, or an output vector). In some cases, a supervised learning algorithm analyzes the training data and produces the inferred function, which is used for mapping new examples. In some cases, the learning results in a function that correctly determines the class labels for unseen instances. In other words, the learning algorithm generalizes from the training data to unseen examples.

In some cases, the training component trains the machine learning model by updating the machine learning parameters of the machine learning model according to the loss function. In some cases, the training component trains the machine learning model to generate a label for a user segment from the database of users based on the loss function. in some cases, the training component trains the machine learning model to generate one or more summary statistics for a user segment from the database of users based on the loss function. In some cases, the training component trains the machine learning model to generate a behavioral prediction for the user segment based on the loss function.

The description and drawings described herein represent example configurations and do not represent all the implementations within the scope of the claims. For example, in some cases, the operations and steps can be rearranged, combined, or otherwise modified. Also, in some cases, structures and devices are represented in the form of block diagrams to represent the relationship between components and avoid obscuring the described concepts. In some cases, similar components or features have the same name but have different reference numbers corresponding to different figures.

In some cases, some modifications to the disclosure are readily apparent to those skilled in the art, and the principles defined herein can be applied to other variations without departing from the scope of the disclosure. Thus, the disclosure is not limited to the examples and designs described herein, but is to be accorded the broadest scope consistent with the principles and novel features disclosed herein.

In some cases, the described methods are implemented or performed by devices that include a general-purpose processor, a digital signal processor (DSP), an application specific integrated circuit (ASIC), a field programmable gate array (FPGA) or other programmable logic device, discrete gate or transistor logic, discrete hardware components, or any combination thereof. In some cases, a general-purpose processor is a microprocessor, a conventional processor, controller, microcontroller, or state machine. In some cases, a processor is also implemented as a combination of computing devices (e.g., a combination of a DSP and a microprocessor, multiple microprocessors, one or more microprocessors in conjunction with a DSP core, or any other such configuration). Thus, in some cases, the functions described herein are implemented in hardware or software and are executed by a processor, firmware, or any combination thereof. In some cases, if implemented in software executed by a processor, the functions are stored in the form of instructions or code on a computer-readable medium.

Computer-readable media includes both non-transitory computer storage media and communication media including any medium that facilitates transfer of code or data. In some cases, a non-transitory storage medium is any available medium that is accessible by a computer. For example, in some cases, non-transitory computer-readable media comprises random access memory (RAM), read-only memory (ROM), electrically erasable programmable read-only memory (EEPROM), compact disk (CD) or other optical disk storage, magnetic disk storage, or any other non-transitory medium for carrying or storing data or code.

Also, in some cases, connecting components are properly termed computer-readable media. For example, if code or data is transmitted from a website, server, or other remote source using a coaxial cable, fiber optic cable, twisted pair, digital subscriber line (DSL), or wireless technology such as infrared, radio, or microwave signals, then the coaxial cable, fiber optic cable, twisted pair, DSL, or wireless technology are included in the definition of medium. Combinations of media are also included within the scope of computer-readable media.

In this disclosure and the following claims, the word “or” indicates an inclusive list such that, for example, the list of X, Y, or Z means X or Y or Z or XY or XZ or YZ or XYZ. Also the phrase “based on” is not used to represent a closed set of conditions. For example, in some cases, a step that is described as “based on condition A” is based on both condition A and condition B. In other words, the phrase “based on” shall be construed to mean “based at least in part on.” Also, the words “a” or “an” indicate “at least one.”

What is claimed is:

1. A method for data clustering, comprising:
receiving, by a machine learning model, a prompt;
generating, using the machine learning model, a structured query for a database of users based on the prompt; and
generating, using a user experience platform, a user segment of the users based on the structured query.

2. The method of claim 1, further comprising:
identifying, using the user experience platform, a data trend, wherein the prompt is based on the data trend.

3. The method of claim 1, further comprising:
generating, using the machine learning model, a label of the user segment.

4. The method of claim 3, further comprising:
identifying, using the machine learning model, one or more attributes of the user segment, wherein the label is based on the one or more attributes.

5. The method of claim 1, further comprising:
generating, using the machine learning model, one or more summary statistics of the user segment.

6. The method of claim 1, further comprising:
receiving, by the machine learning model, an additional prompt; and
modifying, using the user experience platform, the user segment based on the additional prompt.

7. The method of claim 1, further comprising:
receiving, via a user interface, a query about the user segment; and
generating a response to the query using the machine learning model.

8. The method of claim 1, further comprising:
generating, using the machine learning model, a behavioral prediction for the user segment.

9. A method for data clustering, comprising:
obtaining, using a training component, training data that includes a training prompt and a ground-truth structured query; and
training, using the training component, a machine learning model to generate structured queries for a database of users using the training data.

10. The method of claim 9, further comprising:
training, using the training component, the machine learning model to generate a label for a user segment from the database of users.

11. The method of claim 9, further comprising:
training, using the training component, the machine learning model to generate one or more summary statistics for a user segment from the database of users.

12. The method of claim 9, further comprising:
training, using the training component, the machine learning model to generate a behavioral prediction for a user segment from the database of users.

13. An apparatus for data clustering, comprising:
at least one processor;
at least one memory storing instructions executable by the at least one processor;
a machine learning model including parameters stored in the at least one memory and trained to generate a structured query for a database of users based on a prompt; and
a user experience platform configured to generate a user segment of the users based on the structured query.

14. The apparatus of claim 13, wherein:
the machine learning model comprises a large language model.

15. The apparatus of claim 13, wherein:
the machine learning model comprises a transformer.

16. The apparatus of claim 13, wherein:
the machine learning model is further trained to generate a label of the user segment.

17. The apparatus of claim 16, wherein:
the label is based on one or more attributes of the user segment.

18. The apparatus of claim 13, wherein:
the machine learning model is further trained to generate one or more summary statistics of the user segment.

19. The apparatus of claim 13, wherein:
the machine learning model is further trained to generate a response to a query about the user segment.

20. The apparatus of claim 13, wherein:
the machine learning model is further trained to generate a behavioral prediction for the user segment.
